(19) United States
(12) Patent Application Publication
(10) Pub. No.: US 2008/0169547 A1
(43) Pub. Date: Jul. 17, 2008

(54) SEMICONDUCTOR MODULES WITH ENHANCED JOINT RELIABILITY

(75) Inventor: Hyung-Gil BAEK, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/971,846

(22) Filed: Jan. 9, 2008

(30) Foreign Application Priority Data
Jan. 16, 2007 (KR) 10-2007-0004896

(51) Int. Cl. H01L 23/538

(52) U.S. Cl. 257/686; 257/E23.169

(57) ABSTRACT

Provided is a semiconductor module with enhanced joint reliability. The semiconductor module includes a package, a printed circuit board (PCB), and conductive joint structures for electrically connecting the package with the PCB. The PCB includes at least one buffer layer that can alleviate the thermal deformation of the semiconductor module due to a difference in the coefficient of thermal expansion between the PCB and the conductive joint structures.

### CROSS-REFERENCE TO RELATED APPLICATION

This application claims priority under 35 USC §119 to Korean Patent Application No. 10-2007-0004896, filed on Jan. 16, 2007, the contents of which are herein incorporated by reference in their entirety.

### BACKGROUND

1. Technical Field

The present invention relates to semiconductor modules, and more particularly, to semiconductor modules with enhanced joint reliability.

2. Description of the Related Art

A semiconductor fabrication process generally includes a front-end process for fabricating integrated circuit (IC) chips on a wafer using photolithography, deposition, and etching processes and a back-end process for assembling and packaging the respective IC chips. The main purposes of the back-end process are as follows:

1. Protection of the IC chips from environmental and handling damage.

2. Formation of interconnection lines used to transmit input/output signals from/to the IC chips.

3. Physical support of the IC chips.

4. Dissipation of heat from the IC chips.

In addition, with an increase in the integration density of semiconductor devices and the spread of portable electronic devices, the demand for advanced package technology that enables the fabrication of lightweight and thin semiconductor packages with better electrical performance at low cost has increased. In order to satisfy these technical requirements, a Package on Package (PoP), a chip-scale package (CSP), and a wafer-level package (WLP) have recently been proposed.

FIG. 1 is a cross-sectional view of a conventional semiconductor module.

Referring to FIG. 1, the conventional semiconductor module includes a printed circuit board (PCB) 10, upper and lower packages 20 and 25 attached to the PCB 10, and solder bumps 40 and 45 for electrically connecting the upper and lower packages 20 and 25 with the PCB 10. Each of the upper and lower packages 20 and 25 includes at least one semiconductor chip that is fabricated through the foregoing front-end process. In this case, since the PCB 10, the packages 20 and 25, and the solder bumps 40 and 45 have different coefficients of thermal expansion, they may be deformed due to thermal stress applied therebetween when a temperature is varied.

The thermal deformation of the components of the semiconductor module deteriorates the joint reliability of the solder bumps 40 and 45. More specifically, the upper and lower packages 20 and 25 may be deformed due to the thermal stress, so that an interval between the PCB 10 and each of the upper and lower packages 20 and 25 may vary with position along the PCB 10. For example, as illustrated in FIG. 1, an interval t2 between an edge of the PCB 10 and the upper package 20 may be greater than an interval t1 between the center of the PCB 10 and the upper package 20, with the result that there may be disconnections between the solder bumps 40 and 45 and the PCB 10 or between the upper and lower packages 20 and 25. In particular, as illustrated in FIG. 1, when the upper and lower packages 20 and 25 are attached to both sides of the PCB 10, the upper and lower packages 20 and 25, but not the PCB 10, are deformed, thereby greatly degrading the joint reliability of the semiconductor module.

### SUMMARY

According to an aspect of the present invention, a semiconductor module with enhanced joint reliability is provided. Also, according to another aspect of the present invention, a semiconductor module that can prevent the degradation of joint reliability due to thermal stress is provided.

In one embodiment, there is provided a semiconductor module including a buffer layer that can alleviate the thermal deformation of the semiconductor module due to a difference in the coefficient of thermal expansion between a printed circuit board (PCB) and conductive joint structures. The semiconductor module includes an upper package including an upper semiconductor chip; the PCB including upper internal terminals used for connecting the upper package with the PCB; and the conductive joint structures for electrically connecting the upper package with the PCB. The PCB includes at least one buffer layer.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principles of the invention. In the drawings:

FIG. 1 is a cross-sectional view of a conventional semiconductor module;

FIGS. 2A and 2B are cross-sectional views of a semiconductor module according to an embodiment of the present invention;

FIGS. 3A and 3B are cross-sectional views of a semiconductor module according to another embodiment of the present invention;

FIGS. 4A through 4F are cross-sectional views illustrating the arrangement of a buffer layer on a printed circuit board (PCB) according to various embodiments of the present invention;

FIG. 5 is a perspective view of a PCB including a via structure according to the present invention; and

FIG. 6 is a cross-sectional view of a semiconductor module according to yet another embodiment of the present invention.

### DETAILED DESCRIPTION

Reference will now be made in detail to the preferred embodiments of the present invention, examples of which are illustrated in the accompanying drawings. However, the present invention is not limited to the embodiments illustrated hereinafter, and the embodiments herein are rather introduced to provide easy and complete understanding of the scope and spirit of the present invention.

It will also be understood that when a layer is referred to as being “on” another layer or substrate, it can be directly on the other layer or substrate, or intervening layers may also be present. In the drawings, the thicknesses of layers and regions are exaggerated for clarity. It will be understood that although the terms first and second are used herein to describe various regions, layers and/or sections should not be limited by these terms. These terms are only used to distinguish one region, layer or section from another region, layer or section. Thus, for example, a first layer discussed below could be termed a second layer without departing from the teachings of the present invention. Each embodiment described and illustrated herein includes complementary embodiments thereof.

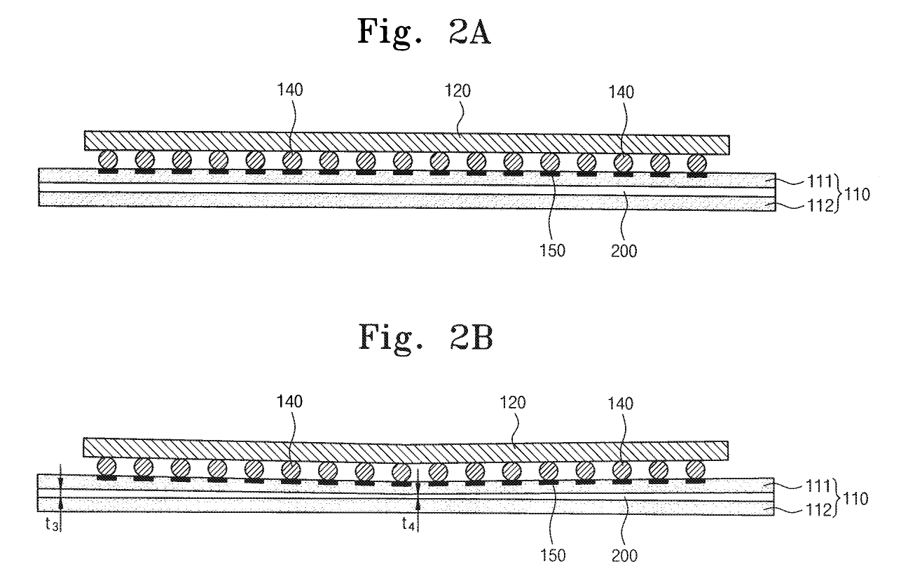

FIGS. 2A and 2B are cross-sectional views of a semiconductor module according to an embodiment of the present invention. Specifically, FIG. 2B illustrates how to alleviate the thermal deformation of the semiconductor module shown in FIG. 2A.

Referring to FIG. 2A, the semiconductor module includes a printed circuit board (PCB) having upper internal terminals 150, an upper package 120 disposed over one surface (e.g., a top surface) of the PCB 110, and upper conductive joint structures 140 for electrically connecting the upper package 120 with the PCB 110. In this case, the upper conductive joint structures 140 are respectively attached to the upper internal terminals 150 of the PCB 110. The upper package 120 includes at least one semiconductor chip fabricated through a front-end process, as described above. The upper conductive joint structures 140 may include solder bumps, and the PCB 110 may include an FR4 layer.

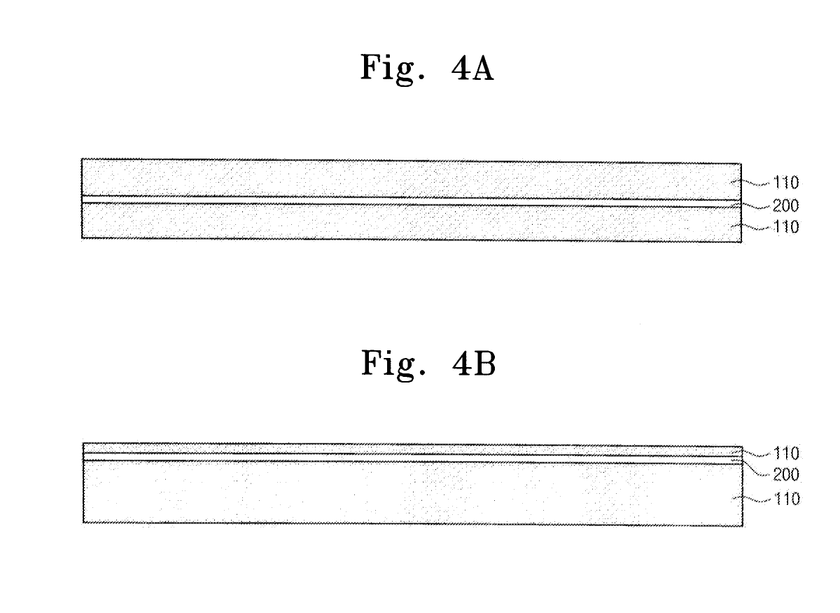

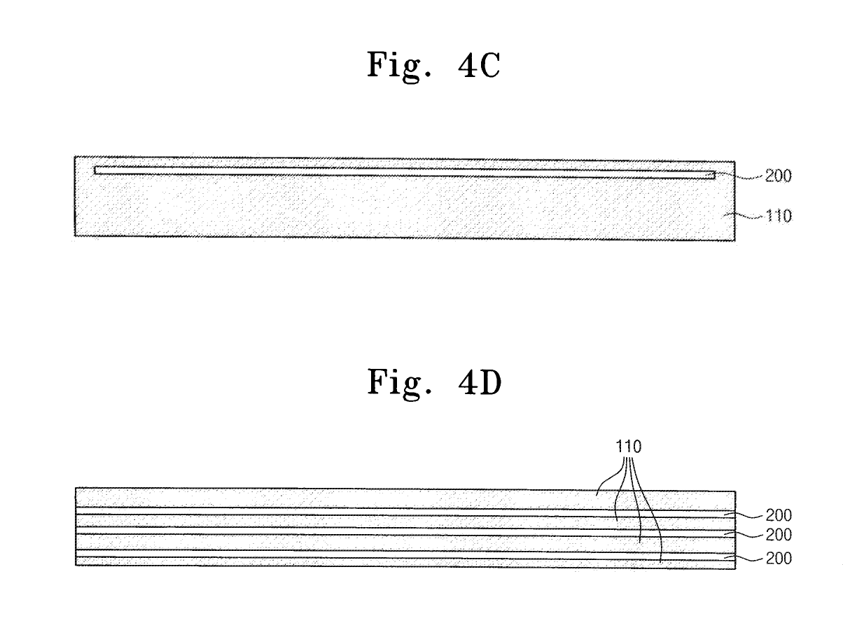

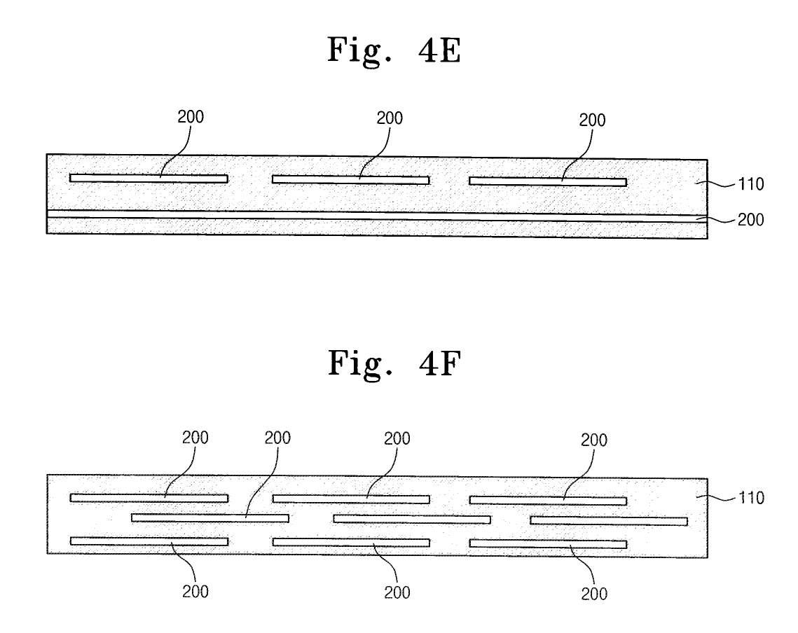

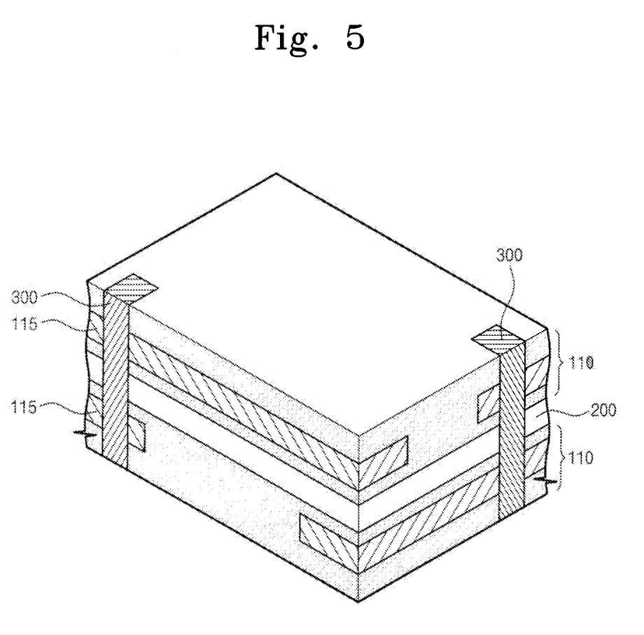

The coefficient of thermal expansion (CTE) of the upper package 120 including the semiconductor chip may range from about 1 to 5 ppm/° C., the CTE of the PCB 110 may range from about 15 to 20 ppm/° C., and the CTE of the upper conductive joint structures 140 may range from about 18 to 25 ppm/° C. In order to prevent the thermal deformation of the semiconductor module due to a difference in the CTEs of the constituent parts, the PCB 110 according to the present invention includes a buffer layer 200. In the present embodiment, as illustrated in FIG. 2A, the buffer layer 200 may be inserted into the PCB 110 so that the PCB 110 is divided into two substrate layers 111 and 112. However, the structure and arrangement of the buffer layer 200 may be variously changed as described in detail later with reference to FIGS. 4A through 4F.

The buffer layer 200 may be formed of at least one of materials having a Young's modulus of about 10 MPa to 1 GPa, preferably, about 10 to 100 MPa. For example, the buffer layer 200 may be formed of at least one of silicon compounds, rubber compounds, photosensitive resins, and synthetic resins. Also, in order to effectively prevent the thermal deformation of the semiconductor module, the buffer layer 200 may have a thickness of about 5 μm to 50 μm, preferably, about 20 μm to 50 μm.

The semiconductor module according to the present invention as described with reference 30 to FIG. 2A can have enhanced joint reliability even if the semiconductor module is thermally deformed due to a difference in the coefficient of thermal expansion between the foregoing components. Referring to FIG. 2B, when the buffer layer 200 is formed of a material having a low Young's modulus as described above, thermal stress caused by a difference in the CTE between the PCB 110 and the upper package 120 can be alleviated by the deformation of the buffer layer 200. Specifically, when the thermal stress is applied, the shape (e.g., thickness) of the buffer layer 200 is changed so that the PCB 110 has substantially the same curvature as the upper package 120. For instance, as illustrated in FIG. 2B, the buffer layer 200 is deformed such that a thickness t₄ of a central portion of the buffer layer 200 differs from a thickness t₃ of an edge portion thereof.

Owing to the deformation of the buffer layer 200, the PCB 110 can have substantially the same curvature as the upper package 120 as described above. Thus, reduced thermal stress is applied to the upper conductive joint structures 140 interposed between the PCB 110 and the upper package 120. As a result, the semiconductor module according to the present invention can have enhanced joint reliability.

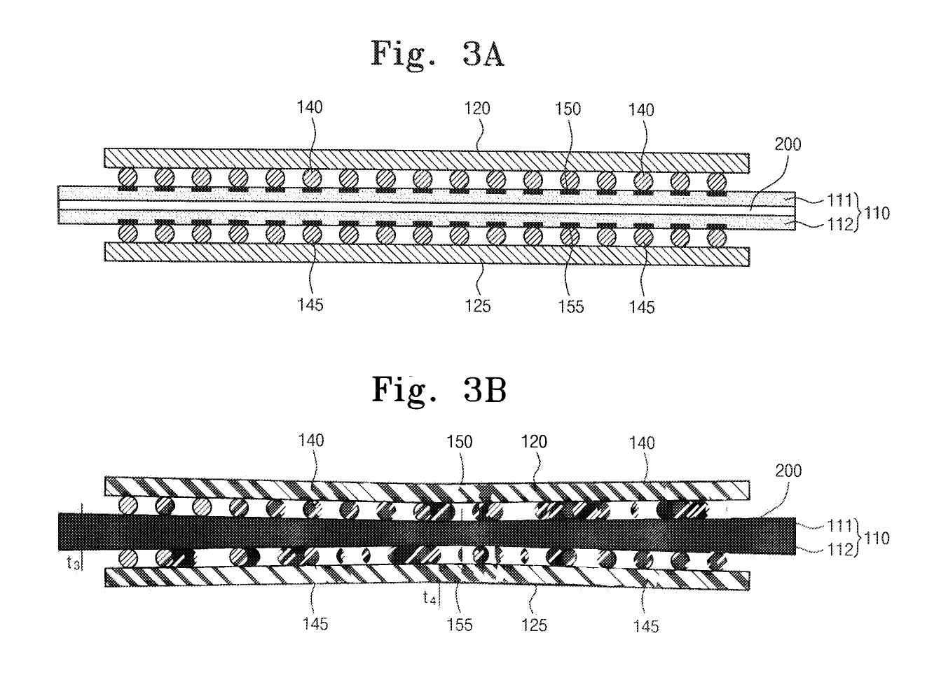

FIGS. 3A and 3B are cross-sectional views of a semiconductor module according to another embodiment of the present invention. Specifically, FIG. 3B illustrates how to alleviate the thermal deformation of the semiconductor module shown in FIG. 3A. The current embodiment is generally similar to the previous embodiment except that packages including semiconductor chips are attached to both the top and bottom surfaces of a single PCB. Thus, the same description as in the previous embodiment will be omitted for brevity.

Referring to FIG. 3A, the semiconductor module further includes a lower package 125 attached to the other side (e.g., the bottom surface) of a PCB 110, compared with the semiconductor module shown in FIG. 2A. The lower package 125 may include at least one semiconductor chip fabricated through the foregoing front-end process, and the lower package 125 is electrically connected to the PCB 110 using lower conductive joint structures 145. According to the present invention, the lower conductive joint structures 145 may be formed of the same material using the same method as the upper conductive joint structures 140. Also, the PCB 110 includes lower internal terminals 155 so that the PCB 110 can be electrically connected to the lower conductive joint structures 145.

In the present embodiment, a buffer layer 200 may be inserted into the PCB 110, similar to the previous embodiment. The physical properties of the buffer layer 200 may be the same as described in the previous embodiment. For example, the buffer layer 200 may be formed of at least one of materials having a Young's modulus of about 10 to 100 MPa and a thickness of about 20 to 50 μm.

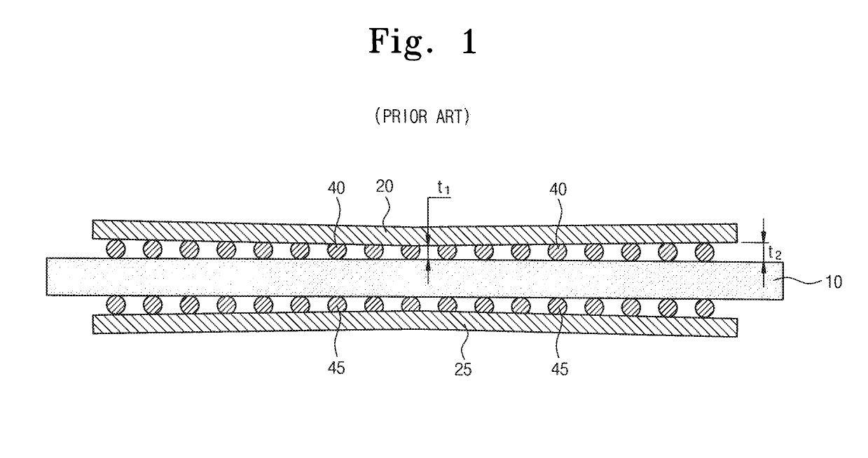

According to experiments conducted by the present inventor, when the buffer layer 200 was not used, a semiconductor module including semiconductor packages attached to both sides of a PCB was more susceptible to thermal stress than a semiconductor module including a semiconductor package attached to one side of a PCB. However, when the buffer layer 200 was used as illustrated in FIG. 3B, even if the semiconductor packages are attached to both sides of the PCB, the thermal stress can be effectively reduced. Specifically, when the present inventor conducted a thermal reliability test, the reliability of the semiconductor module according to the present invention increased to about 5 to 46% more than that of a conventional semiconductor module (e.g., the semiconductor module shown in FIG. 1). Here, the thermal reliability test was conducted by measuring the electrical connection state of solder bumps while repetitively performing a cycle including a process of heating a predetermined semiconductor module and a process of cooling the semiconductor module.

According to the present invention, the structure of the PCB 110 including the buffer layer 200 may be variously changed. FIGS. 4A through 4F are cross-sectional views illustrating the arrangement of the buffer layer 200 in the PCB according to various embodiments of the present invention.

Referring to FIGS. 4A through 4C, a single buffer layer 200 may be inserted into the PCB 110. More specifically, the buffer layer 200 may be inserted into a central portion of the PCB 110 as illustrated in FIG. 4A or inserted into an upper or lower portion of the PCB 110 as illustrated in FIGS. 4B and 4C.

Referring to FIGS. 4D through 4F, a plurality of buffer layers 200 may be inserted into the PCB 110. More specifically, each of the buffer layers 200 may be formed throughout the entire PCB 110 as illustrated in FIG. 4D or partially formed in a predetermined region of the PCB 110 as illustrated in FIGS. 4C and 4F. Furthermore, as illustrated in FIG. 4E, the buffer layer 200 may include a layer extending along the entire PCB 110 and layers formed in partial regions of the PCB 110. Meanwhile, the respective buffer layers 200 may be formed to different thicknesses.

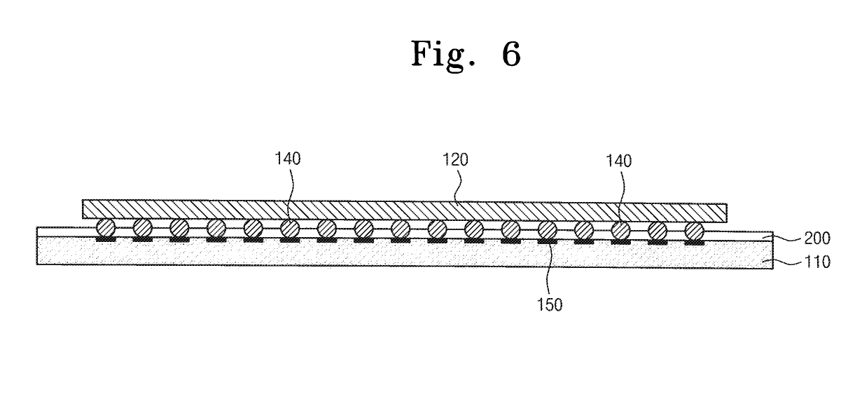

In another embodiment of the present invention, the buffer layer 200 may be formed on the top surface of the PCB 110 to which the upper package 120 is attached, as illustrated in FIG. 6.

According to the present invention, the PCB 110 may include via structures formed through the buffer layer 110. FIG. 5 is a perspective view of a PCB 110 including via structures according to an embodiment of the present invention.

Referring to FIG. 5, the PCB 110 includes interconnection lines 115, which are formed at different levels and separated from one another by the buffer layer 200. According to the present invention, the PCB 110 includes via plugs 300 formed through the buffer layer 200 and connected to the interconnection lines 115 so that the interconnection lines 115 formed at different levels are electrically connected to one another. The formation of the via plugs 300 may include forming via holes through the PCB 110 using a laser drilling technique or a mechanical drilling technique and forming the via plugs 300 using an electroplating technique to fill the via holes.

According to some embodiments of the present invention, a PCB includes a buffer layer that can alleviate the deformation of a semiconductor module due to a difference in the coefficient of thermal expansion between the PCB and a conductive joint structure. Even if the temperature of the semiconductor module is changed, a variation of an interval between a package and the PCB can be reduced throughout the buffer layer. Thus, the joint reliability of the semiconductor module can be enhanced.

According to an aspect of the present invention, there is provided a semiconductor module including a buffer layer that can alleviate the thermal deformation of the semiconductor module due to a difference in the coefficient of thermal expansion between a printed circuit board (PCB) and conductive joint structures. The semiconductor module includes an upper package including an upper semiconductor chip; the PCB including upper internal terminals used for connecting the upper package with the PCB; and upper conductive joint structures for electrically connecting the upper package with the PCB. The PCB includes at least one buffer layer.

The buffer layer may comprise at least one material having a Young's modulus of about 10 MPa to about 1 GPa. For example, the buffer layer may comprise at least one material having a Young's modulus of about 10 MPa to about 100 MPa. Furthermore, the buffer layer may comprise at least one of a silicon compound, a rubber compound, a photosensitive resin, and a synthetic resin. The buffer layer may have a thickness of about 5 μm to about 50 μm.

In an embodiment of the present invention, the coefficient of thermal expansion of the upper package including the upper semiconductor chip may range from about 1 ppm/° C. to about 5 ppm/° C., the coefficient of thermal expansion of the PCB may range from about 15 ppm/° C. to about 20 ppm/° C., and the coefficient of thermal expansion of the upper conductive joint structure may range from about 18 ppm/° C. to about 25 ppm/° C. In this case, the buffer layer may be formed of a material that alleviates the thermal deformation of the semiconductor module due to a difference in the coefficient of thermal expansion between the PCB and the conductive joint structure.

In an embodiment of the present invention, the PCB may include at least two substrate layers and the buffer layer may be interposed between the substrate layers.

In an embodiment of the present invention, the PCB may further include via structures formed through the buffer layer to electrically connect the substrate layers.

In another embodiment of the present invention, the buffer layer may be disposed on the top surface of the PCB adjacent to the conductive joint structures.

In an embodiment of the present invention, the conductive joint structures may include solder bumps attached to the upper internal terminals, respectively.

In another embodiment of the present invention, the semiconductor module may further include a lower package disposed under the PCB. In this case, the PCB may further include lower internal terminals used for connecting the lower package with the PCB.

It will be apparent to those skilled in the art that various modifications and variations can be made in the present invention without deviating from the inventive principles described herein. Thus, it is intended that the present invention covers the modifications and variations of this invention provided they come within the scope of the appended claims and their equivalents.

What is claimed is:

1. A semiconductor module comprising:
an upper package including an upper semiconductor chip;
a printed circuit board (PCB) including upper internal terminals used for connecting the upper package with the PCB; and
upper conductive joint structures for electrically connecting the upper package with the PCB,
wherein the PCB includes at least one buffer layer.

2. The module according to claim 1, wherein the buffer layer comprises at least one material having a Young's modulus of about 10 MPa to about 1 GPa.

3. The module according to claim 2, wherein the buffer layer comprises at least one material having a Young's modulus of about 10 MPa to about 100 MPa.

4. The module according to claim 2, wherein the buffer layer comprises at least one of a silicon compound, a rubber compound, a photosensitive resin, and a synthetic resin.

5. The module according to claim 1, wherein the buffer layer has a thickness of about 5 μm to about 50 μm.

6. The module according to claim 5, wherein the buffer layer has a thickness of about 20 μm to about 50 μm.

7. The module according to claim 1, wherein the coefficient of thermal expansion of the upper package including the upper semiconductor chip ranges from about 1 ppm/° C. to about 5 ppm/° C., the coefficient of thermal expansion of the PCB ranges from about 15 ppm/° C. to about 2 ppm/° C., and the coefficient of thermal expansion of the upper conductive joint structures ranges from about 18 ppm/° C. to about 25 ppm/° C., and
wherein the buffer layer alleviates the thermal deformation of the semiconductor module due to a difference in the coefficient of thermal expansion between the PCB and the conductive joint structure.

8. The module according to claim 1, wherein the PCB includes at least two substrate layers and the buffer layer is interposed between the substrate layers.

9. The module according to claim 8, wherein the PCB further includes via structures formed through the buffer layer to electrically connect the substrate layers.

10. The module according to claim 1, wherein the buffer layer is disposed on the top surface of the PCB adjacent to the upper conductive joint structures.

11. The module according to claim 1, wherein the upper conductive joint structures include solder bumps attached to the upper internal terminals, respectively.

12. The module according to claim 1, further comprising:
a lower package disposed under the PCB; and
lower conductive joint structures electrically connecting the lower package with the PCB,
wherein the PCB further includes lower internal terminals used for connecting the lower package with the PCB.

13. The module according to claim 1, wherein the at least one buffer layer comprises a single layer disposed at a central portion of the PCB and extending along a substantially entire length of the PCB.

14. The module according to claim 1, wherein the at least one buffer layer comprises a single layer disposed at an upper or lower portion of the PCB.

15. The module according to claim 1, wherein the at least buffer e e a plurality of buffer layers disposed in the PCB.

16. The module according to claim 1, wherein the at least one buffer layer comprises a first buffer layer extending along a substantially entire length of the PCB and a plurality of second buffer layers partially extending along the length of the PCB.

17. A semiconductor module, comprising:
a printed circuit board (PCB) including upper internal terminals and lower internal terminals;
an upper package disposed on a first surface of the PCB, the upper package including an upper semiconductor chip;
a lower package disposed on a second surface of the PCB, the lower package including a lower semiconductor chip;
upper conductive joint structures electrically connecting the upper package with the PCB;
lower conductive joint structures electrically connecting the lower package with the PCB;
at least one buffer layer disposed in the PCB;
a plurality of interconnection lines on the first and second surfaces of the PCB; and
a plurality of via plugs disposed in the PCB and electrically connecting the interconnection lines.

18. The semiconductor module of claim 17, wherein the upper conductive joint structures and the lower conductive joint structures are solder bumps.

19. The semiconductor module of claim 17, wherein the at least one buffer layer comprises a plurality of buffer layers disposed in the PCB.
